(19) United States
(12) Patent Application Publication
(10) Pub. No.: US 2025/0386120 A1
(43) Pub. Date: Dec. 18, 2025

(54) PIXEL OF IMAGE SENSOR

(71) Applicant: SAMSUNG ELECTRONICS CO., LTD., Suwon-si (KR)

(72) Inventors: Eunsub SHIM, Suwon-si (KR); Junseok KIM, Suwon-si (KR); Jaeho LEE, Suwon-si (KR)

(73) Assignee: SAMSUNG ELECTRONICS CO., LTD., Suwon-si (KR)

(21) Appl. No.: 19/020,485

(22) Filed: Jan. 14, 2025

(30) Foreign Application Priority Data
Jun. 13, 2024 (KR) 10-2024-0077161

(51) Int. Cl. H04N 25/78; H04N 25/771; H10F 39/00

(52) U.S. Cl. CPC H04N 25/78; H04N 25/771; H10F 39/8037

(57) ABSTRACT

A pixel includes a first pixel circuit including at least one transfer transistor and configured to output a first pixel signal, a photoelectric conversion element having a first end coupled with the first pixel circuit, and a second pixel circuit coupled with a second end of the photoelectric conversion element. The second pixel circuit includes a current mirror circuit configured to amplify an output current output from the second end of the photoelectric conversion element, and an amplification current processing circuit configured to output a second pixel signal based on the amplified output current.

### CROSS-REFERENCE TO RELATED APPLICATIONS

This application claims benefit of priority under 35 U.S.C. § 119 to Korean Patent Application No. 10-2024-0077161, filed on Jun. 13, 2024, in the Korean Intellectual Property Office, the disclosure of which is incorporated by reference herein in its entirety.

### BACKGROUND

### 1. Field

The present disclosure relates generally to a pixel of an image sensor, and more particularly, to a pixel of an image sensor that utilizes both electrons and holes of a photoelectric conversion element.

### 2. Description of Related Art

An image sensor may refer to a semiconductor element that may convert an externally incident optical signal into an electrical signal and may generate image information corresponding to the incident optical signal. Recently, with developments of the computer industry and/or communication industry, demand for image sensors may have increased in various fields, such as, but not limited to, digital cameras, camcorders, mobile phones, security cameras, medical micro cameras, or the like. Although image sensors may generate images with acceptable image quality, image sensors may have difficulty in generating images on certain imaging environments.

### SUMMARY

One or more example embodiments of the present disclosure provide a pixel of an image sensor that utilizes both electrons and holes of a photoelectric conversion element.

According to an aspect of the present disclosure, a pixel includes a first pixel circuit including at least one transfer transistor and configured to output a first pixel signal, a photoelectric conversion element having a first end coupled with the first pixel circuit, and a second pixel circuit coupled with a second end of the photoelectric conversion element. The second pixel circuit includes a current mirror circuit configured to amplify an output current output from the second end of the photoelectric conversion element, and an amplification current processing circuit configured to output a second pixel signal based on the amplified output current.

According to an aspect of the present disclosure, a pixel includes a first pixel circuit including at least one transfer transistor and configured to output a first pixel signal, a photoelectric conversion element having a first end coupled with the first pixel circuit, and a second pixel circuit coupled with a second end of the photoelectric conversion element. The second pixel circuit includes a current mirror circuit configured to amplify an output current output from the second end of the photoelectric conversion element, and an amplification current processing circuit configured to output a second pixel signal based on the amplified output current. The amplification current processing circuit includes a first processing circuit including a reset transistor, and a second processing circuit including at least two capacitors and configured to remove reset noise.

According to an aspect of the present disclosure, a pixel includes a first pixel circuit including at least one transfer transistor and configured to output a first pixel signal, a photoelectric conversion element having a first end coupled with the first pixel circuit, and a second pixel circuit coupled with a second end of the photoelectric conversion element. The second pixel circuit includes a current mirror circuit configured to amplify an output current output from the second end of the photoelectric conversion element, and an amplification current processing circuit configured to output a second pixel signal based on the amplified output current. The amplification current processing circuit includes a dynamic random access memory (DRAM) capacitor.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a block diagram illustrating an image sensor, according to an embodiment;

FIGS. 2A to 2C illustrate implementation examples of pixel arrays corresponding to color filter arrays, according to an embodiment;

FIGS. 3A and 3B are block diagrams respectively illustrating circuit diagrams of pixels, according to embodiments;

FIGS. 4A and 4B are circuit diagrams respectively illustrating structures of a first pixel circuit and a current mirror circuit, according to embodiments;

FIGS. 5A and 5B are circuit diagrams of pixels, according to embodiments;

FIGS. 6A and 6B are circuit diagrams of pixels, according to embodiment;

FIGS. 7A and 7B are circuit diagrams of pixels, according to embodiments;

FIG. 8 is a block diagram illustrating a structure of a pixel, according to an embodiment;

FIG. 9 is a circuit diagram of a pixel, according to an embodiment;

FIG. 10 is a timing diagram illustrating turn-on timing of transistors included in a noise removal circuit of FIG. 9, according to an embodiment; and

FIGS. 11 and 12 are timing diagrams illustrating turn-on timing of transistors included in a noise removal circuit, according to an embodiment.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

Reference throughout the present disclosure to “one embodiment,” “an embodiment,” “an example embodiment,” “the embodiment”, or similar language may indicate that a particular feature, structure, or characteristic described in connection with the indicated embodiment is included in at least one embodiment of the present solution. Thus, the phrases “in one embodiment”, “in an embodiment,” “in an example embodiment,” “according to the embodiment”, and similar language throughout this disclosure may, but do not necessarily, all refer to the same embodiment. The embodiments described herein are example embodiments, and thus, the disclosure is not limited thereto and may be realized in various other forms.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

Hereinafter, various embodiments of the present disclosure are described with reference to the accompanying drawings.

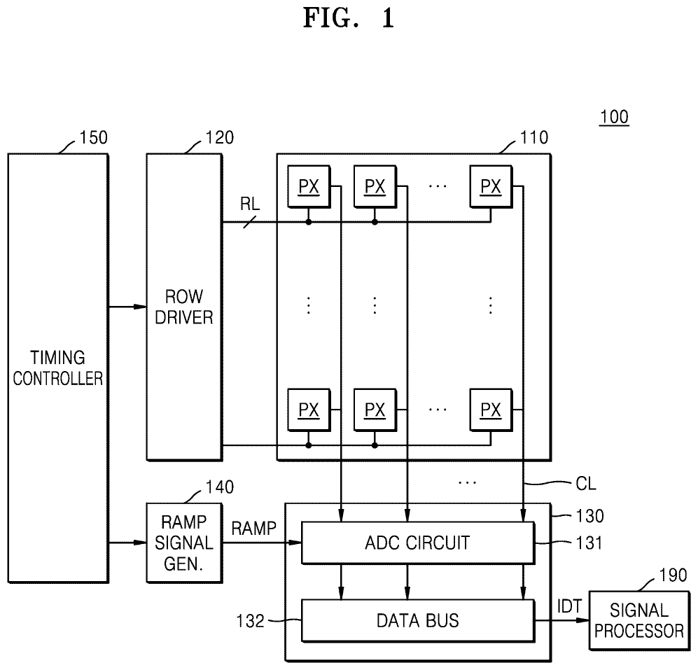

FIG. 1 is a block diagram illustrating an image sensor, according to an embodiment.

An image sensor 100 may be mounted on an electronic device including an image or light sensing function. For example, the image sensor 100 may be mounted on an electronic device, such as, but not limited to, a camera, a smartphone, a wearable device, an Internet of Things (IoT) device, a home appliance, a tablet computer, a personal computer (PC), a personal digital assistant (PDA), a portable multimedia player (PMP), a navigation device, a drone, an advanced driver assistance system (ADAS), or the like. Additionally, the image sensor 100 may be mounted on electronic devices that may be included, as components or the like, in vehicles, furniture, manufacturing facilities, doors, various measurement devices, or the like. The present disclosure is not limited in this regard.

Referring to FIG. 1, the image sensor 100 may include a pixel array 110, a row driver 120, a readout circuit 130, a ramp signal generator 140, a timing controller 150, and a signal processor 190, and the readout circuit 130 may include an analog-to-digital conversion (ADC) circuit 131 and a data bus 132.

The pixel array 110 may include a plurality of row lines RL, a plurality of column lines CL, and a plurality of pixels PX which may be connected to the plurality of row lines RL and the plurality of column lines CL, and may be arranged in rows and columns. The plurality of pixels PX may be shared pixels. Alternatively or additionally, the plurality of pixels PX may be and/or may include sub-pixels.

Each of the plurality of pixels PX may include at least one photoelectric conversion element. The plurality of pixels PX may each detect light by using the photoelectric conversion element and output an image signal, which may be an electrical signal, according to the detected light. For example, the photoelectric conversion element may be and/or may include a light-sensitive element, which may be composed of an organic material and/or an inorganic material, such as, but not limited to, an inorganic photodiode, an organic photodiode, a perovskite photodiode, a phototransistor, a photogate, a pinned photodiode, or the like. In one embodiment, each of the plurality of pixels PX may include a plurality of photoelectric conversion elements. Hereinafter, for the sake of convenience of description, it may be assumed that the photoelectric conversion element is a photodiode. However, the present disclosure is not limited in this regard. That is, the aspects presented herein may be applied to other types of photoelectric conversion elements.

In an embodiment, a micro lens for focusing light may be arranged on an upper portion of each of the plurality of pixels PX, or on an upper portion of a pixel group including adjacent pixels PX. Each of the plurality of pixels PX may detect light of a certain spectrum range from the light received through a micro lens arranged on an upper portion of each of the plurality of pixels PX. For example, the pixel array 110 may include a red pixel R for converting light in a red spectrum range into an electrical signal, a green pixel G for converting light in a green spectrum range into an electrical signal, a blue pixel B for converting light in a blue spectrum range into electrical signals, and a white pixel W for controlling noise. A color filter may be arranged on an upper portion of each of the plurality of pixels PX to transmit light in a certain spectrum range therethrough. However, the present disclosure is not limited thereto, and the pixel array 110 may include pixels that convert light in a spectrum range, other than the red pixel, the green pixel, and the blue pixel, into an electric signal. According to one embodiment, the plurality of pixels PX included in the pixel array 110 may be and/or may include RGBW pixels.

In one embodiment, the plurality of pixels PX may each have a multi-layer structure. The plurality of pixels PX, each having a multi-layer structure, may each include a plurality of stacked photoelectric conversion elements that may convert light in different spectrum ranges into electric signals, and electric signals corresponding to different colors may be generated by the plurality of photoelectric conversion elements. That is, electric signals corresponding to a plurality of colors may be output from a pixel PX.

A color filter array may be arranged on upper portions of the plurality of pixels PX to transmit light in a certain spectrum range therethrough, and a color that may be detected by the pixel PX may be determined according to a color filter arranged on the upper portion of the pixel PX. However, the present disclosure is not limited thereto, and a photoelectric conversion element may also convert light in a certain wavelength band into an electrical signal according to a level of an electrical signal applied to the photoelectric conversion element.

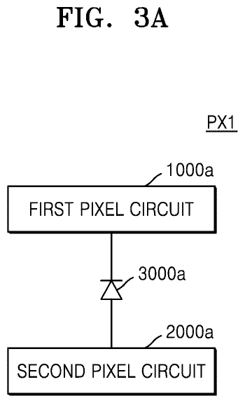

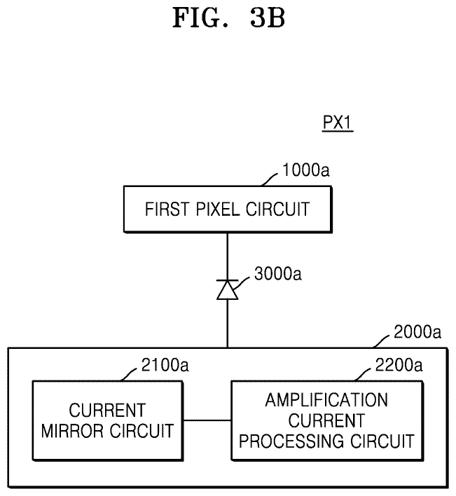

According to an example, each of the plurality of pixels PX may include a first pixel circuit and a second pixel circuit, and the first pixel circuit and the second pixel circuit may share a photodiode included in each of the plurality of pixels PX. According to an example, the first pixel circuit may operate based on electrons of the photodiode, and the second pixel circuit may operate based on holes of the photodiode. According to an example, each of the plurality of pixels PX may output a first pixel signal generated by the first pixel circuit or a second pixel signal generated by the second pixel circuit. Accordingly, efficient pixel signals may be selected and output under various conditions, and thus, the plurality of pixels PX may be efficiently utilized. A structure corresponding to the plurality of pixels PX is described with reference to FIG. 3A.

The row driver 120 may drive the pixel array 110 in units of row lines RL. The row driver 120 may select at least one row line RL from among the row lines RL included in the pixel array 110. For example, the row driver 120 may generate a selection signal SEL for selecting one of the plurality of row lines RL. The pixel array 110 may output a pixel signal from the row line RL selected by the selection signal SEL. The pixel signal may include, but not be limited to, a reset signal and an image signal.

The row driver 120 may generate a plurality of control signals for controlling the pixel array 110. The row driver 120 may independently provide the signals applied to the plurality of control lines. The row driver 120 may provide the plurality of control signals to the plurality of pixels PX in response to a timing control signal output from the timing controller 150.

The timing controller 150 may control timing of the row driver 120, the readout circuit 130, and the ramp signal generator 140. The timing controller 150 may provide control signals for controlling operation timing of each of the row driver 120, the readout circuit 130, and the ramp signal generator 140. The timing controller 150 may determine activation and/or deactivation timing of signals applied to control lines by adjusting timing of a plurality of control line signals generated by the row driver 120.

The ramp signal generator 140 may generate a ramp signal RAMP that may increase and/or decrease at a preset slope and provide the ramp signal RAMP to an ADC circuit 131 of the readout circuit 130.

The readout circuit 130 may read out pixel signals from the pixels PX of the row line RL selected by the row driver 120 among the plurality of pixels PX. The readout circuit 130 may convert the pixel signals received from the pixel array 110 through the plurality of column lines CL into digital data based on the ramp signal RAMP output from the ramp signal generator 140, thereby generating and outputting pixel values corresponding to the plurality of pixels PX in units of row.

The ADC circuit 131 may compare a pixel signal received through each of the plurality of column lines CL with the ramp signal RAMP and generate a pixel value, which may be a digital signal, based on a comparison result. For example, a reset signal may be removed from an image signal, and a pixel value representing the amount of light detected by the pixel PX may be generated. The ADC circuit 131 may sample and hold a pixel signal according to a correlated double sampling (CDS) method, may double sample a level of a certain noise (e.g., a reset signal) and a level according to an image signal, and may generate a comparison signal based on a level corresponding to the difference between the levels. The ADC circuit 131 may also sample a pixel signal provided by first reading out an image signal and subsequently reading out a reset signal, according to a delta reset sampling (DRS) method.

A plurality of pixel values generated by the ADC circuit 131 may be output as image data IDT through the data bus 132. The image data IDT may be provided to an image signal processor 190, which may be located inside and/or outside the image sensor 100.

The data bus 132 may temporarily store the plurality of pixel values output from the ADC circuit 131 and then output the plurality of pixel values. The data bus 132 may include a plurality of column memories and a column decoder. The plurality of pixel values stored in the plurality of column memories may be output as image data IDT under the control of the column decoder.

The signal processor 190 may perform one or more of noise reduction processing, gain adjustment, waveform shaping processing, interpolation processing, white balance processing, gamma processing, edge enhancement processing, binning, or the like on the image data IDT. In some embodiments, the signal processor 190 may synthesize the image data IDT output from the pixel array 110 to generate an output image. In addition, in some embodiments, the signal processor 190 may be included in an external processor of the image sensor 100.

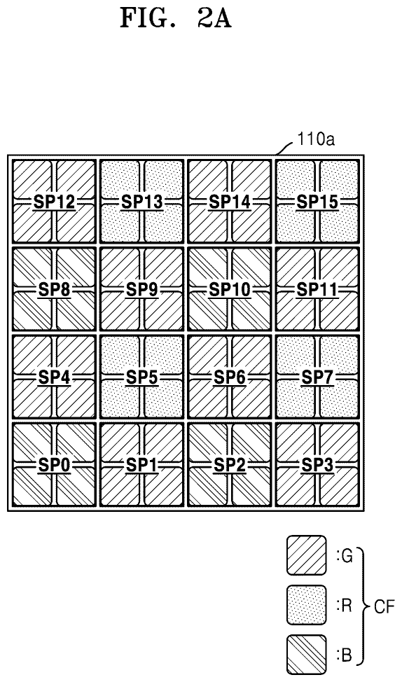

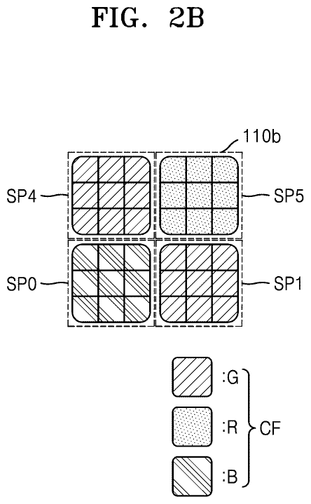

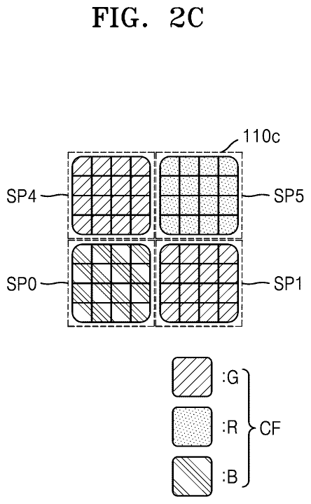

FIGS. 2A to 2C illustrate implementation examples of a pixel array corresponding to a color filter array, according to embodiments.

Referring to FIG. 2A, a pixel array 110a may include a plurality of pixels arranged according to a plurality of rows and columns, and shared pixels defined in unit of pixels arranged in two rows and two columns (e.g., 2×2 array) may each include four (4) sub-pixels. The pixel array 110a may include a plurality of shared pixels (e.g., a first shared pixel SP0, a second shared pixel SP1, a third shared pixel SP2, a fourth shared pixel SP3, a fifth shared pixel SP4, a sixth shared pixel SP5, a seventh shared pixel SP6, an eighth shared pixel SP7, a ninth shared pixel SP8, a tenth shared pixel SP9, an eleventh shared pixel SP10, a twelfth shared pixel SP11, a thirteenth shared pixel SP12, a fourteenth shared pixel SP13, a fifteenth shared pixel SP14, and a sixteenth shared pixel SP15, hereinafter generally referred to as SP). The pixel array 110a may further include a color filter array CF such that the plurality of shared pixels SP may sense various colors.

In one example, the color filter array CF includes filters that sense red (R), green (G), and blue (B), and the plurality of shared pixels SP may each include sub-pixels on which filters having the same color are arranged. For example, the first shared pixel SP0, the third shared pixel SP2, the ninth shared pixel SP8, and the eleventh shared pixel SP10 may include subpixels having a blue (B) color filter, the second shared pixel SP1, the fourth shared pixel SP3, the fifth shared pixel SP4, the seventh shared pixel SP6, the tenth shared pixel SP9, the twelfth shared pixel SP11, the thirteenth shared pixel SP12, and the fifteenth shared pixel SP14 may include subpixels having a green (G) color filter, and the sixth shared pixel SP5, the eighth shared pixel SP7, the fourteenth shared pixel SP13, and the sixteenth shared pixel SP15 may include subpixels having a red (R) color filter.

Additionally, a group including the first shared pixel SP0, the second shared pixel SP1, the fifth shared pixel SP4, and the sixth shared pixel SP5, a group including the third shared pixel SP2, the fourth shared pixel SP3, the seventh shared pixel SP6, and the eighth shared pixel SP7, a group including the ninth shared pixel SP8, the tenth shared pixel SP9, the thirteenth shared pixel SP12, and the fourteenth shared pixel SP13, and a group including the eleventh shared pixel SP10, the twelfth shared pixel SP11, the fifteenth shared pixel SP14, and the sixteenth shared pixel SP15 may be arranged in the pixel array 110a to each correspond to a Bayer pattern. However, the present disclosure is not limited in this regard.

According to an embodiment, a group including the first shared pixel SP0, the second shared pixel SP1, the fifth shared pixel SP4, and the sixth shared pixel SP5, a group including the third shared pixel SP2, the fourth shared pixel SP3, the seventh shared pixel SP6, and the eighth shared pixel SP7, a group including the ninth shared pixel SP8, the tenth shared pixel SP9, the thirteenth shared pixel SP12, and the fourteenth shared pixel SP13, and a group including the eleventh shared pixel SP10, the twelfth shared pixel SP11, the fifteenth shared pixel SP14, and the sixteenth shared pixel SP15 may each correspond to a block of the color filter array CF.

However, this is only an example, and the pixel array 110a, according to the embodiment, may include various types of color filters. For example, the color filter array CF may include filters that sense other colors than red, green, and blue, such as, but not limited to, yellow, cyan, magenta, and white colors. Additionally, the pixel array 110a may include more shared pixels, and the plurality of shared pixels SP may be arranged in various ways.

Referring to a pixel array 110b of FIG. 2B, the first, second, fifth, and sixth shared pixels SP0, SP1, SP4, and SP5 may each include nine (9) sub-pixels. The first shared pixel SP0 may include nine (9) subpixels having a blue (B) color filter, the second shared pixel SP1 and the fifth shared pixel SP4 may each include nine (9) subpixels having a green (G) color filter. The sixth shared pixel SP5 may include nine (9) subpixels having a red (R) color filter. In some embodiments, the first, second, fifth, and sixth shared pixels SP0, SP1, SP4, and SP5 may be referred to as nona cells.

Referring to a pixel array 110c of FIG. 2C, the first, second, fifth, and sixth shared pixels SP0, SP1, SP4, and SP5 may include sixteen (16) sub-pixels. The first shared pixel SP0 may include sixteen (16) subpixels having a blue (B) color filter, and the second shared pixel SP1 and the fifth shared pixel SP4 may each include sixteen (16) subpixels having a green (G) color filter. The sixth shared pixel SP5 may include sixteen (16) subpixels having a red (R) color filter. In some embodiments, the first, second, fifth, and sixth shared pixels SP0, SP1, SP4, and SP5 may be referred to as hexadeca cells.

Shared pixels may include sub-pixels that may be adjacent to each other while having the same color filter. Although FIGS. 2A to 2C illustrate sub-pixels of each of the shared pixels that are arranged in N×N, the arrangement of the sub-pixels included in the shared pixels is not limited to the N×N. As used herein, N may be a positive integer greater than one (1).

FIGS. 3A and 3B are block diagrams illustrating circuit diagrams of pixels, according to embodiments. The pixels described with reference to FIGS. 3A and 3B may include and/or may be similar in many respects to the pixels described above with reference to FIGS. 1, 2A, 2B, and 2C, and may include additional features not mentioned above. Consequently, repeated descriptions of the pixels described above with reference to FIGS. 1, 2A, 2B, and 2C may be omitted for the sake of brevity.

Referring to FIG. 3A, a pixel PX1 may include a photodiode 3000a, a first pixel circuit 1000a connected to one end of the photodiode 3000a, and a second pixel circuit 2000a connected to the other end of the photodiode 3000a. According to the embodiment, a cathode of the photodiode 3000a may be connected to the first pixel circuit 1000a, and an anode of the photodiode 3000a may be connected to the second pixel circuit 2000a.

The first pixel circuit 1000a and the second pixel circuit 2000a may each generate a pixel signal of a voltage according to the amount of charges generated by the photodiode 3000a. The first pixel circuit 1000a included in the pixel PX1, according to the embodiment, may generate a first pixel signal based on electrons generated by the photodiode 3000a, and the second pixel circuit 2000a may generate a second pixel signal based on holes generated by the photodiode 3000a. Therefore, the first pixel circuit 1000a may use a current based on electrons, and the second pixel circuit 2000a may use a current based on holes. In an embodiment, even when electrons accumulate in the photodiode 3000a, a current based on the holes may continuously flow, and thus, the first pixel circuit 1000a may maintain a four-transistor (4T) operation and may operate as a separate circuit from the second pixel circuit 2000a. According to the embodiment, the first pixel circuit 1000a and the second pixel circuit 2000a included in a pixel PX1 may share the photodiode 3000a. According to the embodiment, two (2) pixel signals may be output from one pixel through the first pixel circuit 1000a and the second pixel circuit 2000a which are respectively connected to both ends of the photodiode 3000a, and, as a result, there may be an effect of obtaining a clearer image by using an appropriate pixel signal according to an imaging situation.

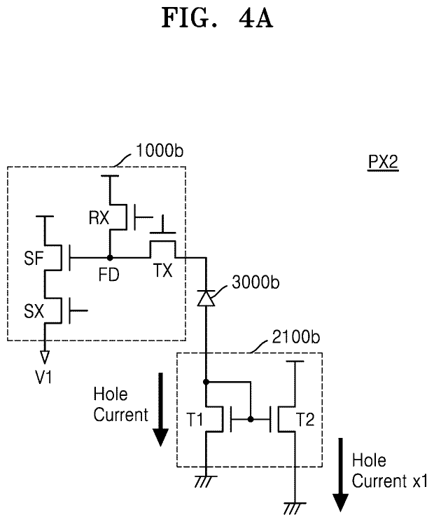

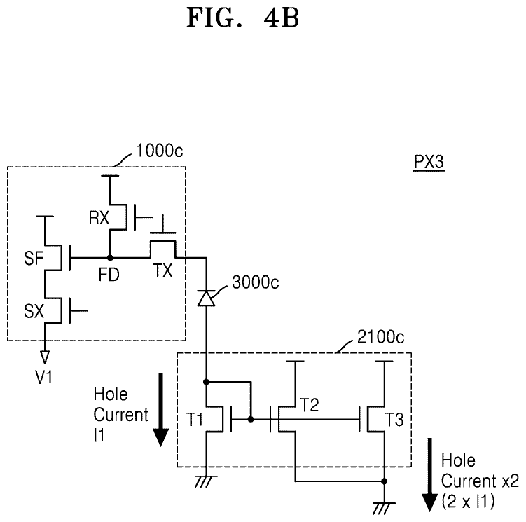

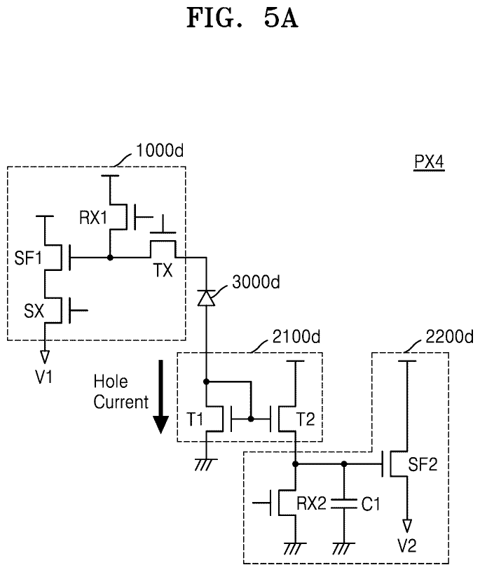

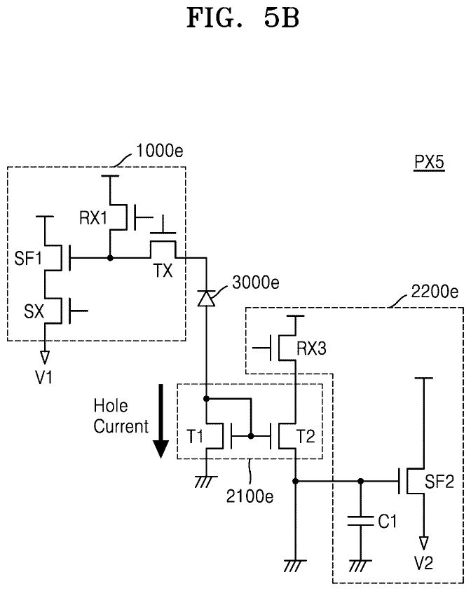

Referring to FIG. 3B, the second pixel circuit 2000a may include a current mirror circuit 2100a and an amplification current processing circuit 2200a. The current mirror circuit 2100a may be connected to the anode of the photodiode 3000a. The current mirror circuit 2100a may copy and/or amplify a hole current generated by the photodiode 3000a by being connected to the anode of the photodiode 3000a. A structure of the current mirror circuit 2100a is described below with reference to FIGS. 4A and 4B. The amplification current processing circuit 2200a may be connected to an output terminal of the current mirror circuit 2100a. The amplification current processing circuit 2200a may include a pixel circuit for outputting the second pixel signal based on a current output from the current mirror circuit 2100a. According to the embodiment, the amplification current processing circuit 2200a may include a pixel circuit having a different circuit structure from a circuit structure of the first pixel circuit 1000a. The circuit structure of the amplification current processing circuit 2200a is described below with reference to FIG. 5A.

Although, in the embodiment, the first pixel circuit 1000a and the second pixel circuit 2000a share only one photodiode 3000a, according to another embodiment, the first pixel circuit 1000a and the second pixel circuit 2000a may share multiple photodiodes. In some embodiments, the first pixel circuit 1000a may be connected to cathodes of a plurality of photodiodes, and the second pixel circuit 2000a may be connected to anodes of the plurality of photodiodes. For the sake of convenience of description, the first pixel circuit and the second pixel circuit that share only one photodiode are described below.

According to the present disclosure, the second pixel circuit connected to an anode of a photodiode is disclosed to utilize a hole current corresponding to holes output from the photodiode. According to the embodiment, the second pixel circuit may include a current mirror circuit and may sense an image in a dark imaging environment by amplifying a hole current. According to the embodiment, the second pixel circuit may periodically reset a current mirror circuit by including a reset transistor, and may configure a pixel circuit capable of operating at a three transistor (3T) operation by including a first capacitor that stores flowed charges. According to the embodiment, the second pixel circuit may remove reset noise of a first processing circuit by including a second processing circuit that includes two (2) or more capacitors. In this case, the second pixel circuit may perform both a global shutter operation and a rolling shutter operation. According to the embodiment, the second pixel circuit may operate as a high dynamic range (HDR) circuit capable of storing overflowed charges by including a dynamic random access memory (DRAM) capacitor. According to the embodiment, a structure of the second pixel circuit may operate separately from the first pixel circuit while sharing photodiodes with the first pixel circuit. Hereinafter, embodiments of the second pixel circuit are further described.

FIGS. 4A and 4B are circuit diagrams illustrating structures of a first pixel circuit and a current mirror circuit, according to embodiments.

Referring to FIG. 4A, a pixel PX2 may include a first pixel circuit 1000b, a photodiode 3000b, and a current mirror circuit 2100b. Although a configuration of an amplification current processing circuit is omitted from FIGS. 4A and 4B for the sake of convenience of description, the amplification current processing circuit may be connected to an output terminal of the current mirror circuit 2100b and/or a current mirror circuit 2100c.

The first pixel circuit 1000b may include a transfer transistor TX that transfers photo-charges generated by the photodiode 3000b to a floating diffusion node FD to detect the photo-charges generated by the photodiode 3000b, a reset transistor RX, a source follower transistor SF, and a select transistor SX. The photodiode 3000b may generate the photo-charges in response to incident light and accumulate the photo-charges in the photodiode 3000b. The photo-charges accumulated in the photodiode 3000b may be selectively transferred to the floating diffusion node FD by the transfer transistor TX and detected as an electrical signal related to an image by operations of the reset transistor RX, the source follower transistor SF, and the select transistor SX.

The floating diffusion node FD may include a floating diffusion region doped with an n-type impurity in a semiconductor layer. The floating diffusion node FD may receive the photo-charges accumulated in the photodiode 3000b and store accumulatively the photo-charges. Additionally, the floating diffusion node FD may be electrically connected to the source follower transistor SF and control an operation of the source follower transistor SF.

The transfer transistor TX may selectively transfer the photo-charges accumulated in the photodiode 3000b to the floating diffusion node FD. The reset transistor RX may be connected between a node supplying a power voltage and the floating diffusion node FD and may reset the photo-charges stored in the floating diffusion node FD.

The source follower transistor SF may be combined with a constant current source that may located outside the pixel PX2 to form a source follower buffer amplifier. The source follower transistor SF may be connected to the floating diffusion node FD and may amplify a potential change of the photo-charges stored in the floating diffusion node FD and convert the photo-charges into a first pixel signal V1.

The select transistor SX may be connected between a source and ground of the source follower transistor SF and may selectively output the first pixel signal V1. The select transistor SX may select a unit pixel to be read in units of row and may transmit the first pixel signal V1 of the selected unit pixel as an image signal along a detection line in a column direction.

Referring to FIG. 4A, one end of the transfer transistor TX included in the first pixel circuit 1000b may be connected to the cathode of the photodiode 3000b, and one end of a first n-channel metal-oxide semiconductor (NMOS) transistor T1 included in the current mirror circuit 2100b may be connected to the anode of the photodiode 3000b. The current mirror circuit 2100b may include the first NMOS transistor T1 and a second NMOS transistor T2. One end of the first NMOS transistor T1 included in the current mirror circuit 2100b may be connected to the anode of the photodiode 3000b, and the other end of the first NMOS transistor T1 may be connected to the ground. A gate of the first NMOS transistor T1 may be connected to a gate of the second NMOS transistor T2. One end of the first NMOS transistor T1 may be connected to the gate of the first NMOS transistor T1. The current mirror circuit 2100b may serve as a current source that may easily supply a current applied to the second pixel circuit.

Referring to FIG. 4B, a pixel PX3 may include a first pixel circuit 1000c, a photodiode 3000c, and a current mirror circuit 2100c. A configuration of the first pixel circuit 1000c may correspond to the configuration of the first pixel circuit 1000b. The current mirror circuit 2100c illustrated in FIG. 4B may include a first NMOS transistor T1, a second NMOS transistor T2, and a third NMOS transistor T3. The current mirror circuit 2100c illustrated in FIG. 4B may include three (3) NMOS transistors to configure a multi-stage current mirror circuit. Accordingly, when a current flowing through the first NMOS transistor T1 is I1, a current flowing through the third NMOS transistor T3 may be 2×I1. In such a manner, by using the multi-stage current mirror circuit, a current may be amplified and provided to the second pixel circuit, and thus, current supply may be controlled to facilitate an operation in low illuminance. According to the embodiment, the pixels PX2 and PX3 may copy and/or amplify a hole current by including the current mirror circuits 2100b and 2100c and may sense an image in a dark imaging environment. In a low-illuminance environment, the amount of current may be relatively small that may cause readout to be difficult. However, in the present disclosure, a current is amplified through a current mirror circuit, and thus, an image may be sensed even in a relatively dark imaging environment.

Circuit structures of the first pixel circuits 1000b and 1000c and the current mirror circuits 2100b and 2100c respectively illustrated in FIGS. 4A and 4B are only examples, and the first pixel circuits 1000b and 1000c may be variously modified in the range of a circuit structure capable of reading out pixel signals, and the current mirror circuits 2100b and 2100c may be variously modified in the range of a circuit structure capable of copying and/or amplifying a current.

Although FIG. 4B illustrates that the current mirror circuit 2100c is connected in two (2) stages, the current mirror circuit 2100c, according to an embodiment, may be connected in N stages by additionally including transistors. According to the embodiment, the current mirror circuit 2100c may amplify a current N times by using one reference transistor and N additional transistors. Current mirror circuits described with reference to the drawings below are examples to which the current mirror circuit illustrated in FIG. 4A is applied, however, the present disclosure is not limited thereto, and the current mirror circuits described with reference to the drawings below may be examples to which the current mirror circuit of FIG. 4B is applied, or may be examples to which a current mirror circuit having a different circuit structure is applied.

FIGS. 5A and 5B are circuit diagrams of pixels, according to embodiments.

A pixel PX4 according to FIG. 5A may include a first pixel circuit 1000d, a photodiode 3000d, a current mirror circuit 2100d, and an amplification current processing circuit 2200d. Configurations of the first pixel circuit 1000d, the photodiode 3000d, and the current mirror circuit 2100d may respectively correspond to the configurations of the first pixel circuit 1000b, the photodiode 3000b, and the current mirror circuit 2100b described above with reference to FIG. 4A, and accordingly, repeated descriptions thereof may be omitted for the sake of brevity.

Referring to FIG. 5A, an example of the amplification current processing circuit 2200d is illustrated. The amplification current processing circuit 2200d may include a second reset transistor RX2, a first capacitor C1, and a second source follower transistor SF2. One end of the second reset transistor RX2 may be connected to one end of the current mirror circuit 2100d, and the other end of the second reset transistor RX2 may be connected to the ground. One end of the first capacitor C1 may be connected to one end of the current mirror circuit 2100d, and the other end of the first capacitor C1 may be connected to the ground. A gate of the second source follower transistor SF2 may be connected to one end of the current mirror circuit 2100d, and a second pixel signal V2 may be output from one end of the second source follower transistor SF2.

Referring to FIG. 5A, the amplification current processing circuit 2200d may not include a transfer transistor. The amplification current processing circuit 2200d may reset an amplified current output from the current mirror circuit 2100d by including the second reset transistor RX2 connected to one end of the current mirror circuit 2100d. The amplification current processing circuit 2200d may periodically reset the amplification current processing circuit 2200d through the second reset transistor RX2. The amplification current processing circuit 2200d resets an amplified current by turning on the second reset transistor RX2 and then turns off the second reset transistor RX2, thereby being able to store, in the capacitor C1, holes flowing out of the photodiode 3000d after the reset. That is, the amplification current processing circuit 2200d may control the time for the holes to be accumulated by controlling turn-off timing of the second reset transistor RX2 and may control effective integration time (EIT) therethrough to output a second pixel signal V2. According to the structure, a pixel circuit may be configured with a smaller number of transistors than a related 4T circuit structure.

Referring to FIG. 5B, a pixel PX5 may include a first pixel circuit 1000e, a photodiode 3000e, a current mirror circuit 2100e, and an amplification current processing circuit 2200e. The pixel PX5 may include and/or may be similar in many respects to the pixel PX4 described above with reference to FIG. 5A, and may include additional features not mentioned above. Consequently, repeated descriptions of the pixel PX5 described above with reference to FIG. 5A may be omitted for the sake of brevity.

The amplification current processing circuit 2200e may include a third reset transistor RX3, a first capacitor C1, and a second source follower transistor SF2. The third reset transistor RX3 may be connected to the other end of the current mirror circuit 2100e. That is, comparing FIG. 5A with FIG. 5B, although FIG. 5A illustrates that the second reset transistor RX2 included in the amplification current processing circuit 2200d is connected to one end of the current mirror circuit 2100d, FIG. 5B illustrates that the third reset transistor RX3 included in the amplification current processing circuit 2200e is connected to the other end of the current mirror circuit 2100e. FIG. 5A and FIG. 5B illustrate embodiments of amplification current processing circuits in which arrangement positions of reset transistors are different from each other.

Referring to the second pixel circuits according to FIGS. 5A and 5B, a hole current may be copied and/or amplified by a current mirror circuit, and a pixel may be read out with a 3T structure. According to the embodiment, a second pixel circuit may periodically reset a current mirror circuit by including a reset transistor and may operate with 3T by including a first capacitor that stores flowing charges. In the present disclosure, a pixel circuit operable with 3T may refer to a pixel circuit including a reset transistor, a source follower transistor, and a select transistor excluding a transfer transistor. It is to be understood that a select transistor connected to one end of a source follower transistor may be omitted from the accompanying drawings for the sake of convenience of description.

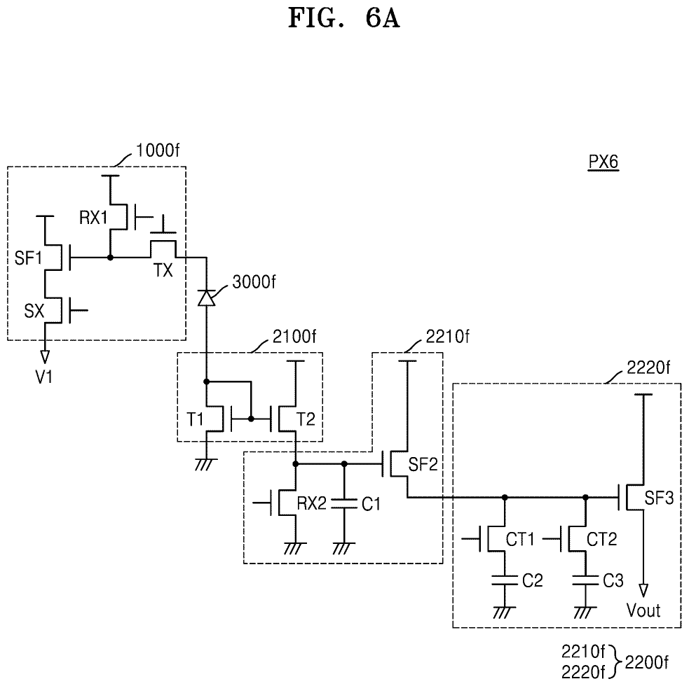

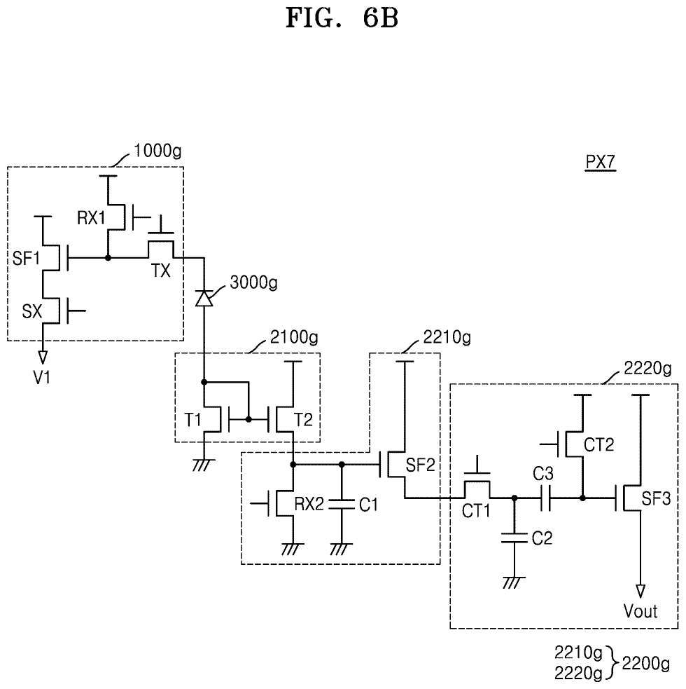

FIGS. 6A and 6B are circuit diagrams of pixels, according to embodiments.

A pixel PX6 of FIG. 6A may include a first pixel circuit 1000f, a photodiode 3000f, a current mirror circuit 2100f, and an amplification current processing circuit 2200f. Configurations of the first pixel circuit 1000f, the photodiode 3000f, and the current mirror circuit 2100f respectively correspond to the configurations of the first pixel circuit 1000b, the photodiode 3000b, and the current mirror circuit 2100b described above with reference to FIG. 4A, and accordingly, repeated descriptions thereof may be omitted for the sake of brevity. The amplification current processing circuit 2200f may include a first processing circuit 2210f and a second processing circuit 2220f.

The first processing circuit 2210f may include a second reset transistor RX2, a first capacitor C1, and a second source follower transistor SF2. A configuration of the first processing circuit 2210f corresponds to the configuration of the amplification current processing circuit 2220d described above with reference to FIG. 5A, and accordingly, repeated description thereof may be omitted for the sake of brevity.

The second processing circuit 2220f may include a first transistor CT1, a second transistor CT2, a second capacitor C2, a third capacitor C3, and a third source follower transistor SF3. According to the embodiment, the second processing circuit 2220f may be connected to an output terminal of the first processing circuit 2210f. The second processing circuit 2220f may include the second capacitor C2 and the third capacitors C3 connected in parallel to each other. The first transistor CT1 may be connected to one end of the second capacitor C2, and ground may be connected to the other end of the second capacitor C2. The second transistor CT2 may be connected to one end of the third capacitor C3, and the ground may be connected to the other end of the third capacitor C3. According to the embodiment, the second capacitor C2 included in the second processing circuit 2220f may store a reset signal level, and the third capacitor C3 included in the second processing circuit 2220f may store an image signal level. According to the embodiment, the second processing circuit 2220f may operate as a global shutter circuit.

According to the embodiment of FIG. 6A, the first processing circuit 2210f may store a voltage level through a first capacitor C1 without including a transfer transistor, and accordingly, EIT may be controlled by controlling turning a second reset transistor RX2 on or off, and floating diffusion node FD reset noise may occur at turn-off timing of the second reset transistor RX2. In the embodiment, for the purpose of reducing influence of the FD reset noise, the second reset transistor RX2 may be controlled to be turned off at a first point in time, and a second source follower transistor SF2 may be controlled to be turned on. In this case, the first transistor CT1 may be turned on to store a corresponding reset level in the second capacitor C2, and then the second transistor CT2 may be turned on at a second point in time to store a corresponding image signal level in the third capacitor C3. By calculating the difference between the reset level stored in the second capacitor C2 and the image signal level stored in the third capacitor C3, a signal level from which the FD reset noise is removed may be obtained, and the influence of the FD reset noise may be reduced.

Referring to FIG. 6B, a pixel PX7 may include a first pixel circuit 1000g, a photodiode 3000g, a current mirror circuit 2100g, and an amplification current processing circuit 2200g. Configurations of the first pixel circuit 1000g, the photodiode 3000g, and the current mirror circuit 2100g respectively correspond to the configurations of the first pixel circuit 1000b, the photodiode 3000b, and the current mirror circuit 2100b described above with reference to FIG. 4A, and accordingly, repeated descriptions thereof may be omitted for the sake of brevity. The amplification current processing circuit 2200g may include a first processing circuit 2210g and a second processing circuit 2220g. The first processing circuit 2210g may correspond to the first processing circuit 2210f of FIG. 6A, and accordingly, repeated descriptions thereof may be omitted for the sake of brevity.

The second processing circuit 2220g of FIG. 6B may include a first transistor CT1, a second transistor CT2, a second capacitor C2, a third capacitor C3, and a third source follower transistor SF3. Comparing to the second processing circuit 2220f of FIG. 6A, an arrangement structure of the first transistor CT1, the second transistor CT2, the second capacitor C2, and the third capacitor C3 may be different from the arrangement structure of the second processing circuit 2220f. The second processing circuit 2220g of FIG. 6B includes the first transistor CT1 connected in series to an output terminal of the first processing circuit 2210g, and the other end of the first transistor CT1 may be connected to a second capacitor C2 and the third capacitor C3. One end of the second capacitor C2 may be connected to the first transistor CT1, and the other end of the second capacitor C2 may be connected to the ground. One end of the third capacitor C3 may be connected to the first transistor CT1, and the other end of the third capacitor C3 may be connected to one end of the second transistor CT2. One end of the second transistor CT2 may be connected to a power supply voltage, and one end of each of the third capacitor C3 and the second transistor CT2 may be connected to a gate of the third source follower transistor SF3. According to the embodiment, a reset level may be stored in the second capacitor C2, and an image signal level may be stored in the third capacitor C3.

According to the embodiment, a second pixel circuit may remove the reset noise generated by a first processing circuit by including a second processing circuit including two (2) or more capacitors. A reset level and an image signal level may be respectively stored in two (2) or more capacitors based on the timing of a reset transistor included in the first processing circuit. The second pixel circuits included in FIGS. 6A and 6B may each perform a rolling shutter operation or a global shutter operation by including the second source follower transistor SF2 included in the first processing circuit and the third source follower transistor SF3 included in the second processing circuit.

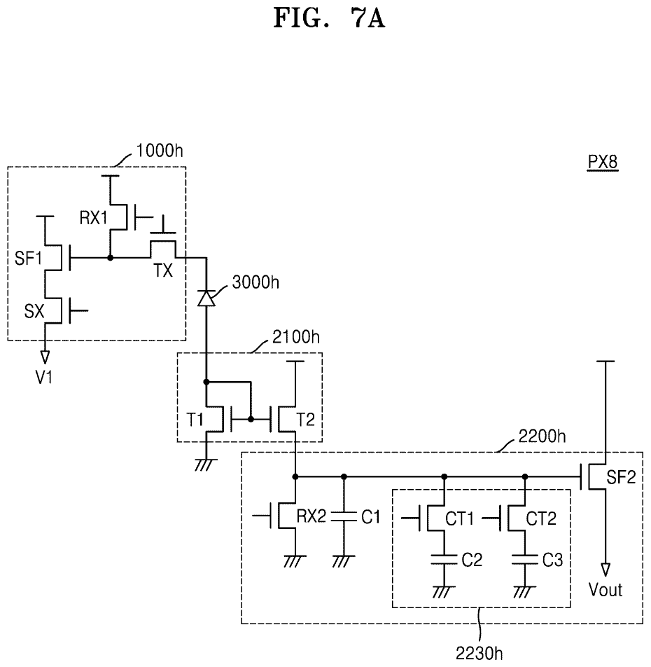

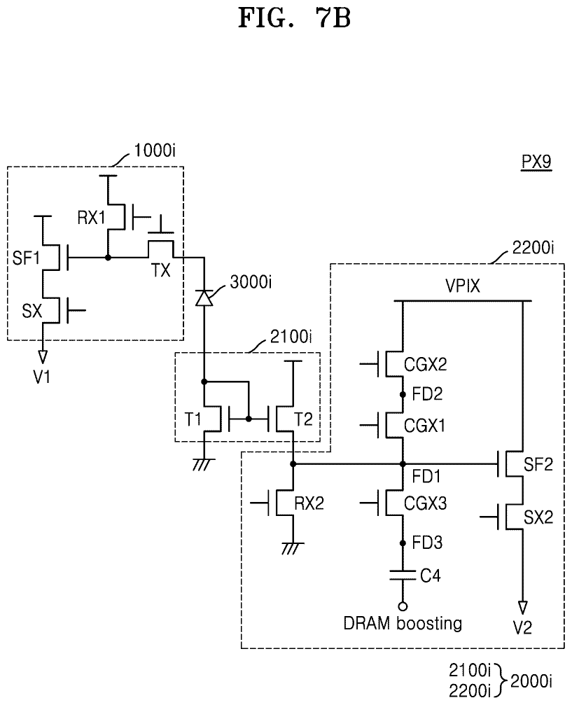

FIGS. 7A and 7B are circuit diagrams of pixels, according to embodiments.

A pixel PX8 of FIG. 7A may include a first pixel circuit 1000h, a photodiode 3000h, a current mirror circuit 2100h, and an amplification current processing circuit 2200h. Configurations of the first pixel circuit 1000h, the photodiode 3000h, and the current mirror circuit 2100h respectively correspond to the configurations of the first pixel circuit 1000b, the photodiode 3000b, and the current mirror circuit 2100b described above with reference to FIG. 4A, and accordingly, repeated descriptions thereof may be omitted for the sake of brevity. The amplification current processing circuit 2200h may include a second reset transistor RX2, a first capacitor C1, a first transistor CT1, a second capacitor C2, a second transistor CT2, a third capacitor C3, and a second source follower transistor SF2.

The amplification current processing circuit 2200h includes the second capacitor C2 connected to the first transistor CT1 and the third capacitor C3 connected to the second transistor CT2, compared to the amplification current processing circuit 2200d of FIG. 5A, and accordingly, overflowing charges may be stored in the second capacitor C2 and the third capacitor C3. According to the embodiment, at least one of the second capacitor C2 and the third capacitor C3 may be a DRAM capacitor. According to the embodiment, the second capacitor C2 and the third capacitor C3 may be capacitors, each having a capacitance of 50 femtoFarads (fF) or more.

A pixel PX9 of FIG. 7B may include a first pixel circuit 1000i, a photodiode 3000i, a current mirror circuit 2100i, and an amplification current processing circuit 2200i. Configurations of the first pixel circuit 1000i, the photodiode 3000i, and the current mirror circuit 2100i respectively correspond to the configurations of the first pixel circuit 1000b, the photodiode 3000b, and the current mirror circuit 2100b described above with reference to FIG. 4A, and accordingly, repeated descriptions thereof may be omitted for the sake of brevity. The amplification current processing circuit 2200i may include a second reset transistor RX2, a first conversion gain control transistor CGX1, a second conversion gain control transistor CGX2, a third conversion gain control transistor CGX3, a fourth capacitor C4, a second source follower transistor SF2, and a second select transistor SX2.

A first floating diffusion node FD1 may be connected to one end of the second reset transistor RX2. The first conversion gain control transistor CGX1 and the second conversion gain control transistor CGX2 may be connected in series to the first floating diffusion node FD1. Charges generated by a photodiode of the pixel PX9 may accumulate in the first floating diffusion node FD1, and the charges accumulated in the first floating diffusion node FD1 may be converted into a voltage. In this case, a ratio at which the charges accumulated in the first floating diffusion node FD1 are converted into a voltage may be referred to as a conversion gain. The conversion gain may vary according to the capacitance of the floating diffusion node FD1. The capacitance of the first floating diffusion node FD1 may be adjusted by controlling turning the first conversion gain control transistor CGX1 and the second conversion gain control transistor CGX2 on and off, and accordingly, a conversion gain of the second pixel circuit 2000i may be adjusted. That is, when the capacitance of the floating diffusion node FD1 increases, the conversion gain may decrease, and when the capacitance of the floating diffusion node FD1 decreases, the conversion gain may increase. The rate at which charges are converted into a voltage may be the highest in a high conversion gain mode where the capacitance of the floating diffusion node FD1 decreases, and may be the lowest in a low conversion gain mode where the capacitance of the floating diffusion node FD1 is higher.

The third conversion gain control transistor CGX3 may be connected to the first floating diffusion node FD1. The fourth capacitor C4 may be connected to one end of the third conversion gain control transistor CGX3. The fourth capacitor C4 may be a DRAM capacitor. The third conversion gain control transistor CGX3 may be turned on to additionally store overflowing charges in the fourth capacitor C4. According to the embodiment, the fourth capacitor C4 may be a capacitor having a capacitance of 50 fF or more.

Referring to FIGS. 7A and 7B, a second pixel circuit may operate as an HDR circuit that may store overflowing charges by having a configuration including a DRAM capacitor, and thus, a dynamic range may be further increased. Additionally, the second pixel circuit may adjust a conversion gain through a plurality of conversion gain control transistors connected to a floating diffusion node. The second pixel circuit, according to the embodiment, may significantly increase a dynamic range by setting a different EIT from the first pixel circuit to adjust overflow charges and EIT.

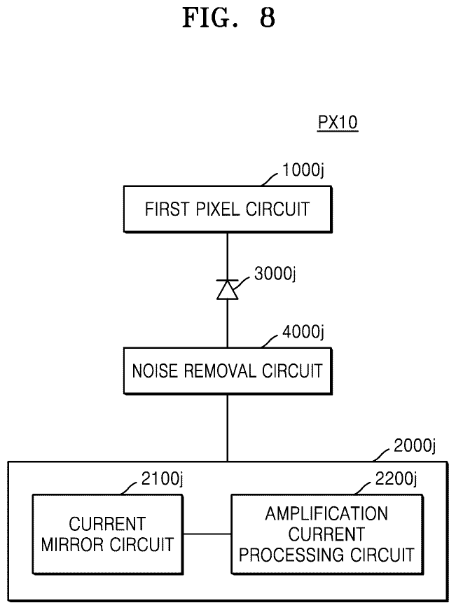

FIG. 8 is a block diagram illustrating a structure of a pixel, according to an embodiment.

Referring to FIG. 8, a pixel PX10 may include a photodiode 3000j, a first pixel circuit 1000j, a second pixel circuit 2000j, and a noise removal circuit 4000j. In describing the pixel PX10 with reference to FIG. 8, the photodiode 3000j, the first pixel circuit 1000j, and the second pixel circuit 2000j respectively correspond to the photodiode, the first pixel circuit, and the second pixel circuit described above with reference to FIGS. 3A to 7B, and accordingly, repeated descriptions thereof may be omitted for the sake of brevity.

According to the embodiment, the second pixel circuit 2000j using holes may generate noise, and when the noise influences a ground level, a signal to noise ratio (SNR) of the first pixel circuit may be influenced thereby. Referring to FIG. 8, the noise removal circuit 4000j may be connected between the photodiode 3000j and the second pixel circuit 2000j. The noise removal circuit 4000j may be connected between an anode of the photodiode 3000j and the second pixel circuit 2000j. The noise removal circuit 4000j may include a plurality of transistors and may remove noise caused by the second pixel circuit 2000j by controlling turning the plurality of transistors on and off.

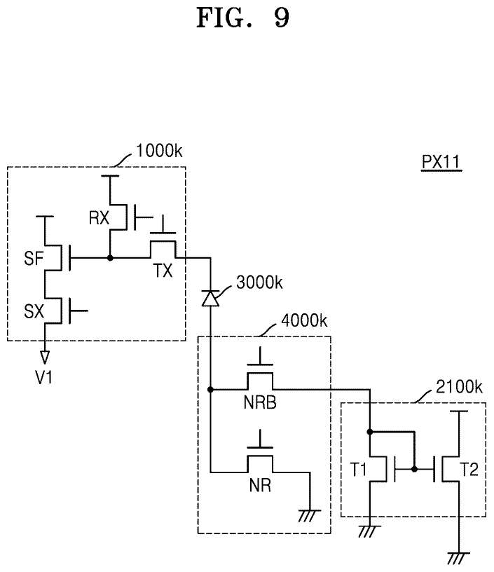

FIG. 9 is a circuit diagram of a pixel, according to an embodiment.

Referring to FIG. 9, a pixel PX11 may include a first pixel circuit 1000k, a current mirror circuit 2100k, a photodiode 3000k, and a noise removal circuit 4000k. According to the embodiment, descriptions of the first pixel circuit 1000k, the current mirror circuit 2100k, and the photodiode 3000k may respectively correspond to the descriptions of the first pixel circuit, the current mirror circuit, and the photodiode given above with reference to FIGS. 3A to 7B, and accordingly, repeated descriptions thereof may be omitted for the sake of brevity.

The noise removal circuit 4000k may include a first transistor NRB and a second transistor NR. According to the embodiment, the first transistor NRB may be connected between an anode of the photodiode 3000k and the current mirror circuit 2100k. The second transistor NR may be connected between the anode of the photodiode 3000k and the ground. According to the embodiment, the first transistor NRB and the second transistor NR may be connected in parallel to each other. The noise removal circuit 4000k may be configured to connect and/or disconnect the current mirror circuit 2100k to and/or from the photodiode 3000k by using the first transistor NRB and the second transistor NR. According to the embodiment, the first transistor NRB of the noise removal circuit 4000k may control a connection between a p-type region of the photodiode 3000k and the current mirror circuit 2100k, and the second transistor NR may control a connection between the p-type region of the photodiode 3000k and the ground, or a certain voltage.

When the first transistor NRB is turned on and the second transistor NR is turned off, the photodiode 3000k may be connected to the current mirror circuit 2100k. In this case, holes generated by the photodiode 3000k may be transferred to the current mirror circuit 2100k. When the first transistor NRB is turned off and the second transistor NR is turned on, the photodiode 3000k may be connected to the ground, and accordingly, the holes generated by the photodiode 3000k may flow to the ground, and thus, a hole current may be drained. In such a manner, by controlling turning the first transistor NRB and the second transistor NR on and off, a connection of the current mirror circuit 2100k to the photodiode 3000k may be controlled.

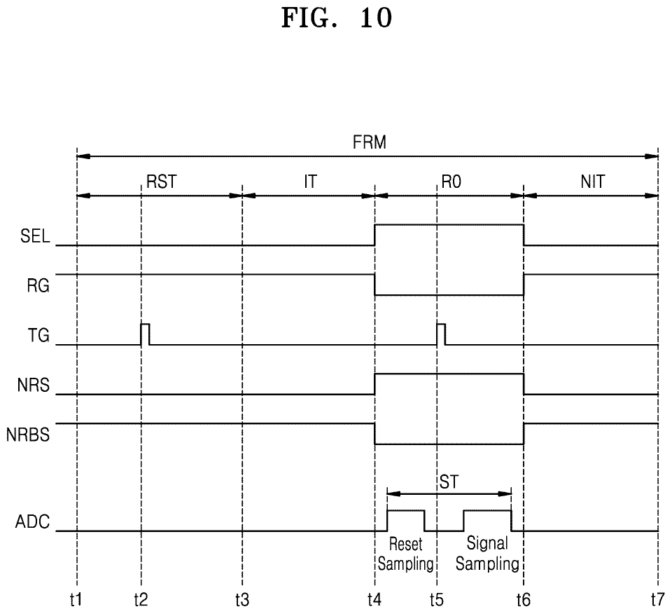

FIG. 10 is a timing diagram illustrating turn-on timing of transistors included in a noise removal circuit of FIG. 9, according to an embodiment.

FIG. 10 illustrates a timing diagram of a selection control signal SEL applied to the select transistor SX of FIG. 9, a reset control signal RG applied to the reset transistor RX of FIG. 9, a transfer control signal TG applied to the transfer transistor TX of FIG. 9, a first control signal NRBS applied to the first transistor NRB of FIG. 9, and a second control signal NRS applied to the second transistor NR of FIG. 9.

FIG. 10 illustrates several periods included in a frame FRM. The frame FRM may include a reset time period RST, an exposure time period IT, a readout time period RO, and a non-integration time period NIT for each of a plurality of rows. The reset time period RST may correspond to an interval between a point in time t1 and a point in time t3, the exposure time period IT may correspond to an interval between the point in time t3 and a point in time t4, the readout time period RO may correspond to an interval between the point in time t4 and a point in time t6, and the non-integration time period NIT may correspond to an interval between the point in time t6 to a point in time t7.

A pixel may be reset during the reset time period RST corresponding to the interval between the point in time t1 and the point in time t3. At a point in time t2, the transfer transistor TX included in the pixel may be turned on to transfer the charges generated by a photodiode during the non-integration time period NIT to a floating diffusion node, and accordingly, the charges may be removed. During the reset time period RST, the reset control signal RG applied to the reset transistor RX may maintain a second level such that the transfer transistor TX of the pixel is turned on in a state where a reset voltage is applied to the floating diffusion node, and accordingly, the floating diffusion node and the pixel may be reset together.

During the exposure time period IT corresponding to the interval between the point in time t3 and the point in time t4, charges according to an optical signal may be generated and accumulated in a photodiode provided in the pixel. During the readout time period RO corresponding to the interval between the point in time t4 and the point in time t6, the pixel may be read out. At a point in time t5, the transfer transistor TX included in the pixel is turned on, and accordingly, the charges accumulated in the photodiode during the exposure time period IT is transferred to the floating diffusion node, and a pixel voltage corresponding to the transferred charges may be output through a column line. During the readout time period R0 before the point in time t5, sampling (reset sampling) of a signal corresponding to the reset voltage may be performed, and during the readout time period R0 after the point in time t5, sampling (signal sampling) of a signal corresponding to an image voltage may be performed. At the point in time t4 that is a start point in time of the readout time period R0, the selection control signal SEL applied to the selection transistor SX may be shifted from a first level to a second level, and the reset control signal RG applied to the reset transistor RX may be shifted from the second level to the first level. At the point in time t6 which is an end point in time of the readout time period R0, the selection control signal SEL applied to the select transistor SX may be shifted from the second level to the first level, and the reset control signal RG applied to the reset transistor RX may be shifted from the first level to the second level. In the embodiment, the first level may be a low level, and the second level may be a high level.

According to the embodiment, the second control signal NRS applied to the second transistor NR may maintain the first level during the reset time period RST, the exposure time period IT, and the non-integration time period NIT, and the second control signal NRS applied to the second transistor NR may maintain the second level during the readout time period RO. According to the embodiment, the first control signal NRBS applied to the first transistor NRB may maintain the second level during the reset time period RST, the exposure time period IT, and the non-integration time period NIT, and the first control signal NRBS applied to the first transistor NRB may maintain the first level during the readout time period RO. According to the embodiment, at the point in time t4 which is a start point in time of the readout time period R0, the second control signal NRS may be shifted from the first level to the second level, and the first control signal NRBS may be shifted from the second level to the first level. According to the embodiment, at the point in time t6 that is an end point in time of the readout time period R0, the second control signal NRS may be shifted from the second level to the first level, and the first control signal NRBS may be shifted from the first level to the second level. According to the embodiment, the first transistor NRB may be complementary to the second transistor NR. When the first transistor NRB is turned on, the second transistor NR may be turned off, and when the first transistor NRB is turned off, the second transistor NR may be turned on.

According to the embodiment, the first control signal NRBS applied to the first transistor NRB may be shifted from the second level to the first level before a CDS sampling time period ST and may be shifted from the first level to the second level after the CDS sampling time period ST. According to the embodiment, the second control signal NRS applied to the second transistor NR may be shifted from the first level to the second level before the CDS sampling time period ST and may be shifted from the second level to the first level after the CDS sampling time period ST. The CDS sampling time period ST may be included in the readout time period R0.

That is, during the readout time period R0, the first transistor NRB is turned off, and the second transistor NR is turned on, and accordingly, a path, which may be connected to the current mirror circuit 2100k, may be blocked during the readout time period R0, and noise, which may be generated by the current mirror circuit 2100k, may be blocked during the readout time period R0. According to the embodiment, the readout time period R0 may be the most noise-vulnerable period, and accordingly, signals applied to the transistors included in the noise removal circuit 4000k, according to the present disclosure, may be controlled to remove noise.

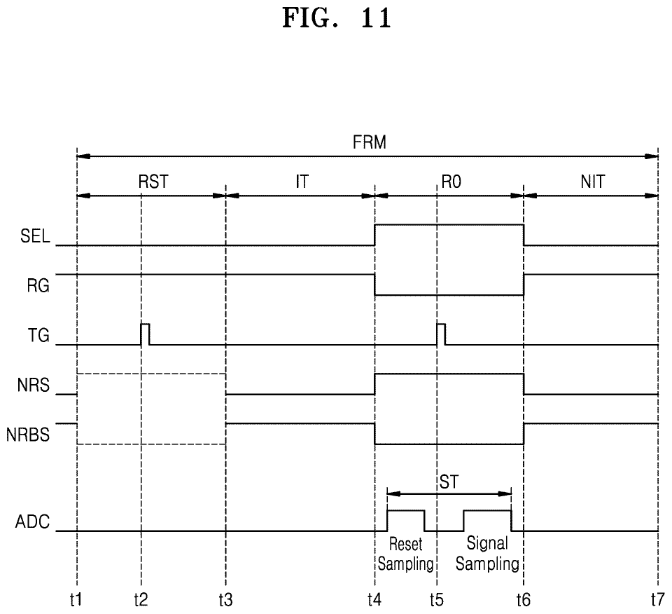

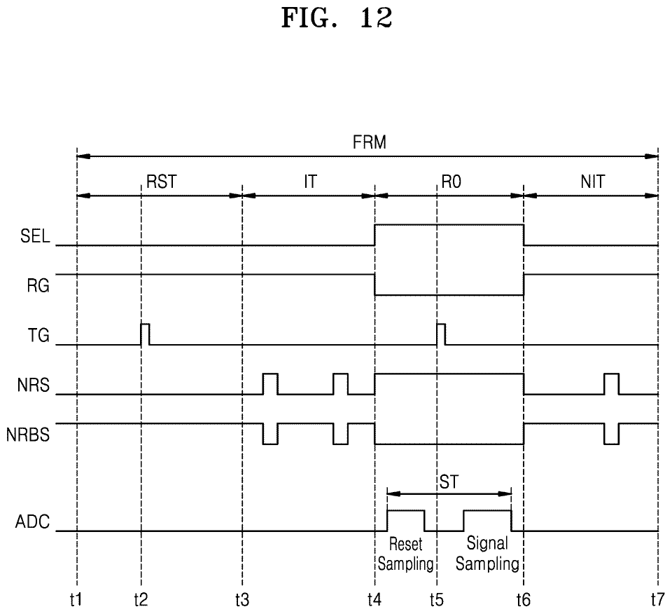

FIGS. 11 and 12 are timing diagrams illustrating turn-on timing of transistors included in a noise removal circuit, according to an embodiment. In describing FIGS. 11 and 12, repeated descriptions with FIG. 10 may be omitted for the sake of brevity.

Referring to FIG. 11, during a reset time period RST corresponding to an interval between a point in time t1 and a point in time t3, the second control signal NRS applied to the second transistor NR may maintain a second level, and the first control signal NRBS applied to the first transistor NRB may maintain a first level. According to the embodiment, at a point in time t1 that is a start point in time of the reset time period RST, the second control signal NRS may be shifted from the first level to the second level, and the first control signal NRBS may be shifted from the second level to the first level. According to the embodiment, at a point in time t3 that is an end point in time of the reset time period RST, the second control signal NRS may be shifted from the second level to the first level, and the first control signal NRBS may be shifted from the first level to the second level.

Referring to the embodiment of FIG. 11, by turning on the second transistor NR and turning off the first transistor NRB during the reset time period RST corresponding to an interval between the point in time t1 and the point in time t3, the pixel may not be influenced by noise that may be generated by the current mirror circuit 2100k, even during a reset operation period.

Although FIGS. 10 to 12 illustrate embodiments in which the second transistor NR is turned on and the first transistor NRB is turned off during the entire reset time period RST and/or the entire readout time period R0, the present disclosure is not be limited thereto, and the second transistor NR may be turned on and the first transistor NRB may be turned off during a time period corresponding to 90% or more of the entire period of the reset time period RST and/or the entire period of the readout time period R0. According to the embodiment, the second transistor NR may be turned off and the first transistor NRB may be turned on during a part of the reset time period RST and/or a part of the readout time period R0. According to the embodiment, in the reset time period RST, the first control signal NRBS may be shifted from the second level to the first level and the second control signal NRS may be shifted from the first level to the second level before a point in time (e.g., a point in time t2) when the transfer control signal TG applied to the transfer transistor TX is shifted from the first level to the second level, and the first control signal NRBS may be shifted from the first level to the second level and the second control signal NRS may be shifted from the second level to the first level after a point in time when the transfer control signal TG applied to the transfer transistor TX is shifted from the second level to the first level.

Referring to the embodiment of FIG. 12, the first control signal NRBS may maintain the first level during a part of the exposure time period IT and the non-integration time period NIT, and the second control signal NRS may maintain the second level during a part of the exposure time period IT and the non-integration time period NIT. According to the embodiment, during a part of the exposure time period IT and the non-integration time period NIT corresponding to a period before and after the readout time of a photodiode, the second transistor NR may be turned on and the first transistor NRB may be turned off. Therethrough, there is an effect of intermittently removing noise that may occur in time periods other than the reset time period RST and the readout time period R0.

In the descriptions of the timing diagrams of FIGS. 10 to 12, the plurality of control signals SEL, RG, TG, NRS, and NRBS described in the timing diagrams may be generated by the row driver 120 of FIG. 1, and the timing control of the plurality of control signals SEL, RG, TG, NRS, and NRBS described in the timing diagrams may be controlled by the timing controller 150 of FIG. 1.

As described above, embodiments are disclosed in the drawings and the present disclosure. In the present disclosure, embodiments are described by using certain terms, but this is only used for the purpose of describing the present disclosure and is not used to limit the meaning or scope of the present disclosure described in claims. Therefore, those skilled in the art are to understand that various modifications and other equivalent embodiments may be derived therefrom. Therefore, the technical protection scope of the present disclosure should be determined by the technical idea of the attached claims.

While the present disclosure has been particularly shown and described with reference to embodiments thereof, it is to be understood that various changes in form and details may be made therein without departing from the spirit and scope of the following claims.

1. A pixel comprising:
a first pixel circuit comprising at least one transfer transistor and configured to output a first pixel signal;
a photoelectric conversion element having a first end coupled with the first pixel circuit; and
a second pixel circuit coupled with a second end of the photoelectric conversion element,
wherein the second pixel circuit comprises:
a current mirror circuit configured to amplify an output current output from the second end of the photoelectric conversion element; and
an amplification current processing circuit configured to output a second pixel signal based on the amplified output current.

2. The pixel of claim 1, wherein the current mirror circuit comprises a plurality of stages.

3. The pixel of claim 1, wherein the amplification current processing circuit comprises a reset transistor coupled with a first end of the current mirror circuit.

4. The pixel of claim 3, wherein the amplification current processing circuit further comprises:
a source follower transistor having a gate coupled with the first end of the current mirror circuit; and
a capacitor coupled with the first end of the current mirror circuit.

5. The pixel of claim 1, wherein the amplification current processing circuit comprises a reset transistor coupled with a second end of the current mirror circuit.

6. The pixel of claim 5, wherein the amplification current processing circuit further comprises:
a source follower transistor having a gate coupled with a first end of the current mirror circuit; and
a capacitor coupled with the first end of the current mirror circuit.

7. The pixel of claim 1, wherein the first pixel circuit is coupled with a cathode of the photoelectric conversion element, and
wherein the second pixel circuit is coupled with an anode of the photoelectric conversion element.

8. The pixel of claim 1, wherein the amplification current processing circuit comprises:
a first processing circuit comprising a reset transistor; and
a second processing circuit comprising at least two capacitors and configured to remove reset noise.

9. (canceled)

10. The pixel of claim 8, wherein the reset transistor is coupled with at least one of a first end of the current mirror circuit and a second end of the current mirror circuit, and
wherein the first processing circuit further comprises:
a first source follower transistor having a gate coupled with the first end of the current mirror circuit; and
a first capacitor coupled with the first end of the current mirror circuit.

11. The pixel of claim 8, wherein the second processing circuit further comprises:
a second capacitor coupled with an output terminal of the first processing circuit; and
a third capacitor coupled with the output terminal of the first processing circuit, and
wherein the second capacitor is coupled in parallel with the third capacitor.

12. The pixel of claim 11, wherein the second capacitor is configured to store a reset level, and
wherein the third capacitor is configured to store a signal level.

13. The pixel of claim 11, wherein the second processing circuit further comprises:
a second source follower transistor having a gate coupled with the output terminal of the first processing circuit; and
at least two transfer transistors configured to respectively control currents applied to the second capacitor and the third capacitor.

14. The pixel of claim 8, wherein the first pixel circuit is coupled with a cathode of the photoelectric conversion element, and
wherein the second pixel circuit is coupled with an anode of the photoelectric conversion element.

15. The pixel of claim 1, wherein the amplification current processing circuit comprises a dynamic random access memory (DRAM) capacitor.

16. The pixel of claim 15, wherein the amplification current processing circuit further comprises:
a reset transistor coupled with a first end of the current mirror circuit; and
a source follower transistor having a gate coupled with the first end of the current mirror circuit.

17. The pixel of claim 15, wherein the amplification current processing circuit further comprises:
a plurality of conversion gain control transistors configured to control a conversion gain of a floating diffusion node of the amplification current processing circuit.

18. The pixel of claim 15, wherein the DRAM capacitor has a capacitance greater than or equal to 50 femtoFarads (fF).

19. (canceled)

20. The pixel of claim 15, wherein the first pixel circuit is coupled with a cathode of the photoelectric conversion element, and
wherein the second pixel circuit is coupled with an anode of the photoelectric conversion element.

21. A pixel, comprising:
a first pixel circuit comprising at least one transfer transistor and configured to output a first pixel signal;
a photoelectric conversion element having a first end coupled with the first pixel circuit; and
a second pixel circuit comprising:
a current mirror circuit configured to amplify an output current output from a second end of the photoelectric conversion element;
a first processing circuit comprising a reset transistor coupled with the current mirror circuit; and
a second processing circuit comprising a plurality of capacitors coupled with an output terminal of the first processing circuit and a plurality of transfer transistors configured to respectively control currents applied to the plurality of capacitors,
wherein the second pixel circuit is configured to output a second pixel signal based on the amplified output current.

22. A pixel, comprising:
a first pixel circuit comprising at least one transfer transistor and configured to output a first pixel signal;
a photoelectric conversion element having a first end coupled with the first pixel circuit; and
a second pixel circuit coupled with a second end of the photoelectric conversion element,
wherein the second pixel circuit comprises:
a current mirror circuit configured to amplify an output current output from the second end of the photoelectric conversion element; and
an amplification current processing circuit comprising a dynamic random access memory (DRAM) capacitor and a plurality of conversion gain control transistors configured to control a conversion gain of a floating diffusion node of the amplification current processing circuit,
wherein the second pixel circuit is configured to output a second pixel signal based on the amplified output current.
